(19) United States
(12) Patent Application Publication
(10) Pub. No.: US 2008/0304229 A1
(43) Pub. Date: Dec. 11, 2008

(54) AIR-PRESSURE-DEPENDENT CONTROL OF COOLING SYSTEMS USING A SHARED AIR PRESSURE SENSOR

(75) Inventors: Michael Sean June, Raleigh, NC (US); Robert Salguero Smith, Dupont, WA (US); Troy Williams Glover, Raleigh, NC (US); Whitcomb Randolph Scott, III, Chapel Hill, NC (US)

Correspondence Address: IBM CORPORATION (SS/NC);c/o STREETS & STEELE, 13831 NORTHWEST FREEWAY, SUITE 355, HOUSTON, TX, 77040, US

(73) Assignee: INTERNATIONAL BUSINESS MACHINES CORPORATION, Armonk, NY (US)

(21) Appl. No.: 11/759,681

(22) Filed: Jun. 7, 2007

(51) Int. Cl. H05K 7/20; G06F 1/16

(52) U.S. Cl. 361/687; 361/695

(57) ABSTRACT

Systems and methods provide altitude-dependent fan control for a plurality of electronic subsystems using a shared air pressure sensor. Each server or multi-server chassis of a rack system is a subsystem of the rack system. Each subsystem receives its own on-board fan or blower module. The shared air pressure sensor senses air pressure and outputs a signal to all of the subsystems. Each subsystem then independently regulates its own fan speed according to the signal output by the shared air pressure sensor. Other fan operational parameters, such as the number of fans recruited, may also be controlled according to altitude according to the invention. A variety of other performance parameters, such as internal air or component temperature, ambient air temperature, server workload, and processor activity level, may also be factored into control of these fan operational parameters.

### BACKGROUND OF THE INVENTION

1. Field of the Invention

The present invention relates to the cooling of electronic systems, and in particular to altitude-dependent cooling of rack-based computer systems.

2. Description of the Related Art

Cooling fans are commonly used to cool electronic devices, such as computers. For example, on-board cooling fans are often installed in individual computer servers, and blower modules are often included within a multi-blade chassis or enclosure to cool multiple blade servers housed in the chassis. It is recognized in the design of such devices that air density and air pressure decrease with increasing altitude, and that lower density air requires higher fan speeds to achieve an equivalent level of cooling. Some cooling fans are, therefore, designed to operate at a single-speed that is fast enough to achieve the desired cooling at any altitude. Consequently, these fans run faster than necessary at lower altitudes, which wastes energy and unnecessarily shortens the lives of the fans.

Some have proposed adding an on-board altimeter to each device, and to regulate the speed of each device's cooling fan in relation to an altitude sensed by the altimeter. One problem with such a solution is that many electronic systems, such as rack-based computer systems, have many different components or subsystems, each requiring its own cooling fan. Equipping each component or subsystem with an on-board altimeter would dramatically increase the cost of the electronic system as a whole. System reliability and maintenance might also suffer because each altimeter is subject to potential failure.

In view of the shortcomings of the prior art, improved cooling systems and methods are needed. In particular, it would be desirable to account for altitude when cooling electronic equipment, without the associated expense and reliability issues inherent to conventional altimeter-based cooling solutions.

### SUMMARY OF THE INVENTION

The invention includes a system and method for altitude-dependent control of airflow parameters for cooling electronic equipment. One embodiment is a computing system having a plurality of heat-generating electronic subsystems in electronic communication with a shared air pressure sensor that generates a signal in relation to sensed air-pressure. Each electronic subsystem includes a cooling fan and a local controller in electronic communication with the shared air pressure sensor and the on-board cooling fan. Each local controller has control logic for controlling one or more operational parameters of the on-board cooling fan in relation to the signal from the shared air pressure sensor.

Another embodiment is a method of cooling an electronic system having a plurality of heat-generating electronic subsystems. Air-pressure of the electronic system is sensed, and a signal is generated in relation to the sensed air-pressure. The signal is communicated to each of the electronic subsystems. One or more fan operational parameters for each electronic subsystem are independently controlled in relation to the signal.

Other embodiments, aspects, and advantages of the invention will be apparent from the following description and the appended claims.

### BRIEF DESCRIPTION OF THE DRAWINGS

FIG. 1 is a front elevation view of a rack-mountable server system in a data center

FIG. 2 is a rear elevation view of the rack-mountable server system, further detailing the components visible from the rear of the server chassis.

FIG. 3 is a schematic diagram of a generalized embodiment of a computer system having a shared air pressure sensor used for air pressure-dependent cooling of multiple subsystems according to the invention.

FIG. 4 is a schematic diagram of another embodiment of the invention providing air pressure-dependent cooling of multiple server chassis of the type shown and described in FIG. 2

FIG. 5 is a schematic diagram of another embodiment of a computer system providing air pressure-dependent cooling of multiple servers using a shared air pressure sensor.

FIG. 6 is a flowchart outlining an embodiment of a method for cooling an electronic system having a plurality of heat-generating subsystems

### DETAILED DESCRIPTION OF PREFERRED EMBODIMENTS

The present invention provides air pressure-dependent fan control for a plurality of electronic subsystems using a shared air pressure sensor. The air pressure sensor in some embodiments is a component of a barometric (pressure) based altimeter. Though the invention may be applied to a variety of electronic systems, the invention is particularly useful as applied to multi-server and/or rack-based computer systems. Each server or multi-server chassis of a rack system is treated as a subsystem of the rack system. Each subsystem receives its own on-board fan or blower module. The shared air pressure sensor senses air pressure and outputs a signal to all of the subsystems. Each subsystem then independently regulates its own fan speed according to the signal output by the shared air pressure sensor. Other fan operational parameters, such as the number of fans recruited, may also be controlled according to air pressure according to the invention. A variety of other performance parameters, such as internal air or component temperature, ambient air temperature, server workload, and processor activity level, may also be factored into control of these fan operational parameters.

The invention has numerous advantages over conventional systems that operate at a single fan speed or range of fan speeds without regard to air pressure. The invention also has advantages over conventional altitude-dependent fan-speed control techniques, which require a separate altimeter for each subsystem. By using a shared air pressure sensor, each subsystem is regulated according to the same air pressure signal, which provides more consistent fan regulation. The use of a shared air pressure sensor also minimizes system cost and improves system reliability by minimizing the number of components used in the system.

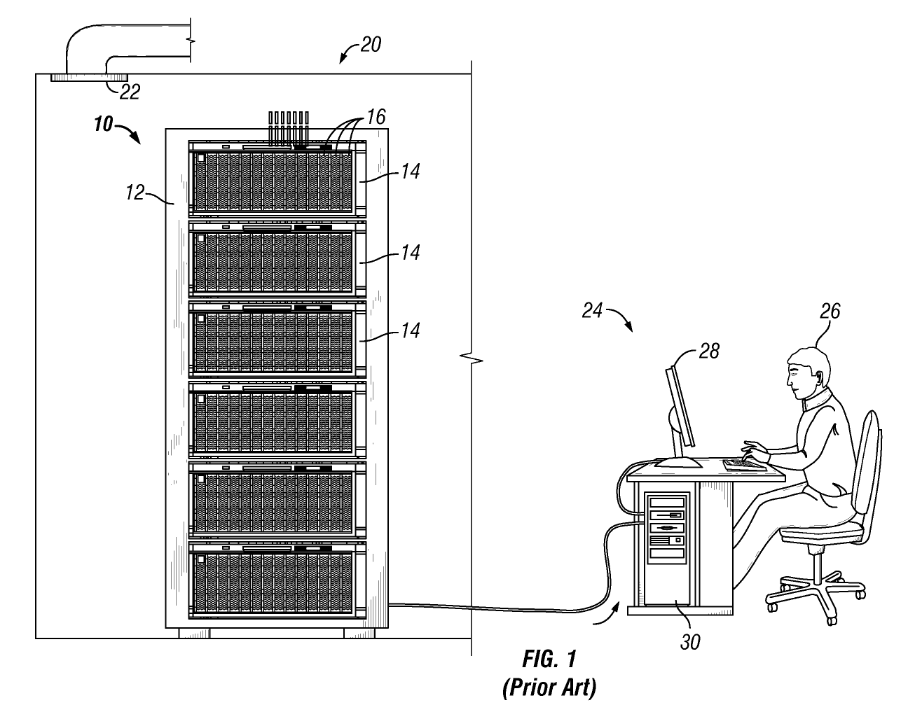

FIG. 1 is a front elevation view of a blower-cooled, rack-mountable server system (“rack system”) 10 in a data center 20. The rack system 10 is shown as just one example, and a wide selection of other rack systems are available from a multitude of companies, such as IBM SYSTEM X servers and IBM eServer BLADECENTER® (IBM, SYSTEM X, and BLADECENTER are trademarks of International Business Machines Corporation of Armonk, N.Y.). The rack system 10 includes a rack 12 supporting six server chassis 14. Each server chassis 14 in this example consists of a 7U by 28-in. (711-mm) deep chassis with a support structure for up to fourteen networked blade servers 16. Thus, the rack 12 holds up to eighty-four heat-generating blade servers and supporting modules, all of which must be cooled. The server chassis 14 each contain a blower module for circulating air through the servers 16 within the chassis of the rack system 10 to cool the components of the rack system 10. Heated air expelled from the rack system 10 is then taken up by an air intake 22 and circulated through a computer-room air-condition system (CRAC) that cools the air and returns it to the data center 20.

A workstation 24 is optionally networked with the servers 16 for helping a system administrator 26 monitor and control the servers 16 globally. The workstation 24 includes a management console 28, which has a customizable graphical administrative interface, and a management server 30, which can remotely support up to thousands of remote computer subsystems including the servers 16. Local software (e.g. a system “agent”) may be installed on each server 16, allowing the management server 30 to selectively interface with the various servers 16 to monitor and control the servers 16. For example, an agent installed on a particular server 16 may warn the system administrator 26 if and when intervention is required for that blade server.

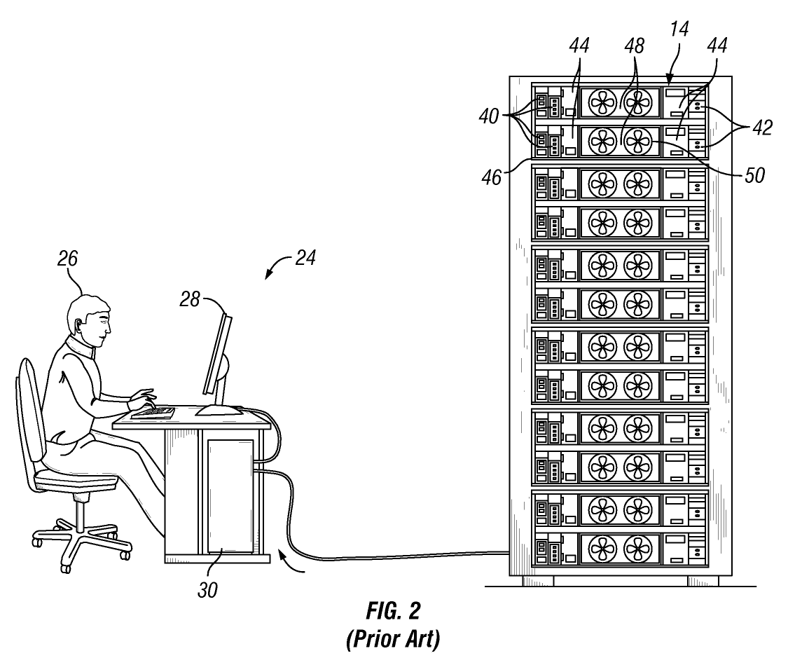

FIG. 2 is a rear elevation view of the rack system 10, further detailing the components visible from the rear of the server chassis 14. Each chassis 14 supports the shared infrastructure for four switch module bays 40, two management module bays 42, four power module bays 44, a rear information panel 46, and two blower modules 48, all of which may interface with one another via an internal midplane. The blower modules 48 move air through the chassis 14 from the front (FIG. 1) to the rear (FIG. 2), thus providing the airflow necessary to keep the servers and supporting modules cool. Each blower module 48 is schematically shown as having two visible fans 50, though any number of fans may be included with a blower module, and the fans are not necessarily visible. Also, the fans 50 may be any of a variety of types known in the art, including axial or radial fans.

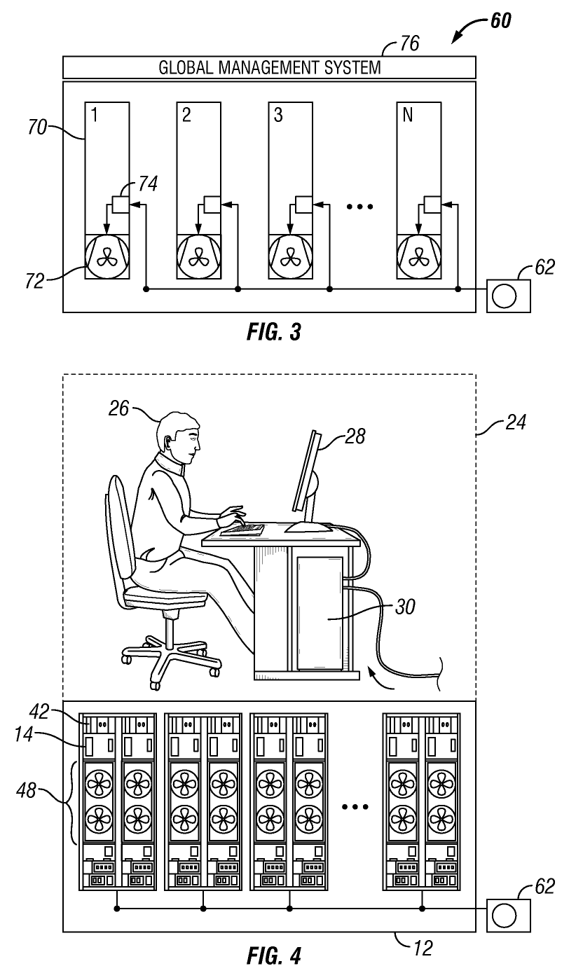

FIG. 3 is a schematic diagram of a generalized embodiment of a computer system 60 configured for air-pressure-dependent cooling of a number of subsystems 70 of the computer system 60 (individual subsystems being numbered 1 through “N” in FIG. 3). Each subsystem 70 includes at least one on-board cooling fan 72 and a local controller 74 for controlling parameters of the fan 72, such as fan speed. Each local controller 74 is in communication with a shared air pressure sensor 62, which may be a component of an electronic barometric altimeter. The shared air pressure sensor 62 generates a signal or message in relation to air-pressure and communicates the signal or message to all N subsystems 70. Each local controller 74 controls the parameters of the associated fan 72 according to the signal from the shared air pressure sensor 62. In particular, each local controller 74 typically controls at least the speed of the associated fan 72 according to air-pressure, such as by providing increased fan speed at lower air pressures typically corresponding to higher altitudes and decreased fan speed at higher air pressures typically corresponding to lower altitudes. An optional global management system 76 may be networked with the N subsystems 70 to provide global monitoring and control of the subsystems 70.

The shared air pressure sensor 62 may be any of a variety of air pressure sensors known in the art having the capability to output an electronic signal representative of air pressure (or a derivative of air pressure, such as altitude or air density). The air pressure sensor 62 may be a component of a barometric altimeter or pressure altimeter. The pressure altimeter may be calibrated to compute, output, and optionally display altitude as a function of air pressure, typically according to a mathematical model set forth by the International Standard Atmosphere (ISA). However, the system of the present invention may also make direct use the air pressure measurement (i.e., pounds per square inch) without ever calculating an altitude (i.e., feet above sea level). Many commercially available altimeters having an air pressure sensor may, therefore, be adapted for use with the invention.

The embodiment of FIG. 3 is generalized to represent applicability of the invention to a variety of computer systems. For example, in a more specific embodiment, the system 60 may represent a rack-system, such as the rack system 10 of FIGS. 1 and 2, wherein each subsystem 70 may be one of the multi-server chassis 14. In another example, the system 60 may be a networked system of self-supporting servers each having its own, on-board cooling fan. In any implementation, the invention provides reliable and cost-effective air-pressure-dependent and altitude-dependent fan control by using the shared air pressure sensor 62 to provide input to controllers that control the fans 72 on all of the subsystems 70.

FIG. 4 is a schematic diagram of a specific embodiment of the invention wherein a computer system, such as the rack system 10 of FIG. 2, is configured for air-pressure-dependent cooling of N server chassis 14 of the type shown and described in FIG. 2. Each server chassis 14, including the servers and supporting modules housed therein, represents one of the N subsystems. The management module 42 of each server chassis 14 acts as a local controller whose numerous capabilities include controlling the heat-generating servers and supporting modules disposed in the server chassis 14. Additionally, the management module 42 controls the blower modules 48 to provide proper cooling of the server chassis 14.

The shared air pressure sensor 62 may be disposed on the rack 12. Each management module 42 is in communication with the shared air pressure sensor 62, and controls the blower modules 48 according to the signal output by the shared air pressure sensor 62. Blower speed is one parameter the management module 42 may control in a manner that considers the altitude or air pressure. For example, at lower altitude, where air density is higher and cooling is more effective at a given airflow rate, each management module 42 may operate its associated blower modules 48 at a lower speed than it might under otherwise identical conditions at a higher altitude. Each server chassis 14 in FIG. 4 is illustrated as having two blower modules 48. In addition to controlling blower/fan speed, the management module 42 may also control which of the blower modules 48 is used. For example, at lower altitudes, the management module 42 might determine, due to the correspondingly higher air pressure, that it is appropriate to only run one of the blower modules 48 or a subset of the fans disposed therein, while at higher altitudes, the management module 42 might run both of the blower modules 48.

In addition to altitude and/or air-pressure, other variables may also be accounted for in operating the blower modules. For example, the management modules 42 may control the associated blower modules 48 according to any set of the variables of internal air or component temperature, ambient air temperature, server workload, processor activity level, or a combination of these variables.

The workstation 24 in this embodiment is one example of a global management system networked with the chassis 14 to globally monitor and control the chassis 14. For example, the management console 28 may display information such as temperatures within the chassis 14, and provide temperature-related alerts such as potential overheating of the servers. The system management server 30 is optionally in communication with the shared air pressure sensor 62 to provide air-pressure information directly to the system administrator 26. If necessary, the workstation 24, in its global management capacity, may have the ability to override the management modules 42. For example, if abnormally high temperatures are sensed within any of the chassis 42, the system management server 30 that is networked to each management module 42 may maximize the blower speed of the affected chassis 42 until the problem has been corrected. Although the shared air pressure sensor 62 is shown as a stand-alone air pressure sensor, the air pressure sensor may also be a component of the workstation 24, such as an air pressure sensor built into the system management server 30. In this manner, the altitude or pressure information may still be communicated to the management modules.

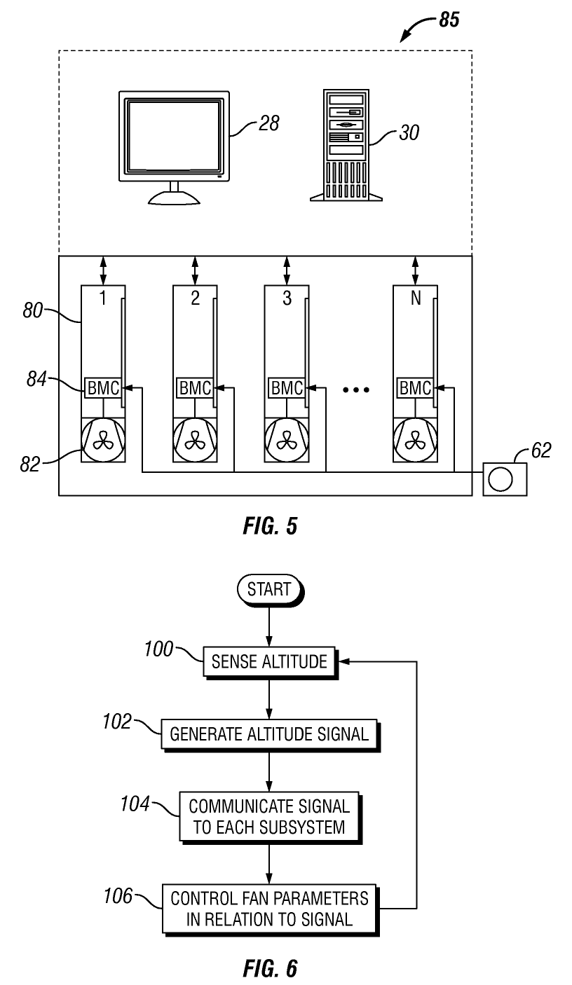

FIG. 5 is a schematic diagram of another specific embodiment of a computer system 85 configured for air-pressure-dependent cooling of N servers 80. The servers 80 in this embodiment each include at least one on-board, variable-speed cooling fan 82, which is in contrast to the blade-type servers 16 of FIG. 1 (which typically do not contain an on-board cooling fan and are instead cooled by chassis blower modules). Each server 80 represents one of N subsystems of the computer system 85. Each server 80 includes a baseboard management controller (BMC) 84, which functions as a local controller for its server 80. In addition to many existing BMC duties known in the art, each BMC 84 also controls the cooling fans 82 in relation to altitude or pressure, to provide proper cooling of the server 80 on which it resides. Each BMC 84 is in communication with the shared air pressure sensor 62. Fan speed is one parameter that the BMC 84 may control according to air-pressure. For example, at lower altitude, where air density is higher and cooling is more effective at a given airflow rate, the BMC 84 may run the associated fan 82 at a lower speed than it would under otherwise identical conditions but at a higher altitude. Although only one, representative fan 82 is shown per server 80, each server 80 in this embodiment may include multiple fans 82. In the case of multiple fans 82 per server 80, the BMC 84 may also control which or how many of the fans 82 are operated at a given altitude under various operating conditions. For example, at lower altitudes, the BMC 84 may only recruit one fan 82 on its associated server 80, and at higher speeds, the BMC 84 may recruit more fans per server 80.

The management server 30 also acts as an optional global management system, wherein the management server 30 may be networked with the servers 80 to globally provide monitoring and selective control of the servers 80. For example, the management server 30 may use the management console 28 to display information such as temperatures of the servers 80, as well as to provide temperature-related alerts such as potential overheating of the servers 80. The management server 30 is optionally in communication with the shared air pressure sensor 62. Thus, the management console 28 may display air-pressure-related and/or altitude-related information and alerts. The management server 30 may operate in cooperation with each BMC 84 to provide control and feedback to the servers 80. Additionally, in its global management capacity, authority of the management server 30 may take precedence over control by the BMCs 84, if necessary. For example, if abnormally high temperatures are sensed within any of the servers 80, the management server 30 networked to each server 80 may increase or maximize the speed of the fans 82 on the affected servers 80 until the problem has been corrected.

FIG. 6 is a flowchart outlining an embodiment of a method for cooling an electronic system having a plurality of heat-generating subsystems. The method may be implemented, for example, on the generalized embodiment of the computer system 60 of FIG. 3 or on the more specific embodiments of FIGS. 5 and 6. The invention is not limited to the particular steps and sequence of steps shown in the flowchart, nor is the invention limited to implementation on the system embodiments shown herein.

In step 100, air-pressure is “sensed,” according to known techniques, in the vicinity of the electronic system. In one example, sensing air-pressure involves obtaining an ambient air pressure reading in the vicinity of the electronic system and, optionally, converting the air pressure reading to an altitude measure according to a known calibration protocol, such as the ISA. An air pressure may be expressed, for example, in pascals (Pa), pounds per square inch (psi), millimeters of mercury (mmHg), or other units of pressure. If an altitude is actually obtained, the altitude measure may be expressed, for example, in meters or feet from sea level, or with respect to another established reference altitude.

In step 102, an electronic signal is generated in relation to the sensed air-pressure, and in step 104, this signal is communicated to each subsystem. Optionally, the air pressure sensor may be a component of an altimeter that converts the air pressure reading to an altitude value. Alternatively, the air pressure sensor may obtain the air pressure reading and generate a signal of the air pressure reading, which the local controller may optionally convert to an altitude value.

In step 106, one or more fan parameters for each subsystem are controlled in relation to the air-pressure signal received by the subsystems in step 104. Typically, the one or more fan parameters include a fan speed for each subsystem. A predefined relationship between air pressure (or derivative thereof, such as altitude) and corresponding desired fan speed may be established. This correlation may be embodied, for example, in an electronic “table,” making fan speed selection a relatively straightforward “table lookup.” Similarly, the correlation may be embodied in a characteristic “curve” established for each subsystem, wherein each characteristic curve plots air-pressure on one axis and fan speed on another axis. Fan speed for each subsystem may be selected according to this predefined relationship.

Another fan parameter that may be controlled in relation to air-pressure is the number of fans recruited on a multi-fan device. For example, a subsystem having three on-board fans may operate all three fans at a higher altitude (and correspondingly lower air pressure), while needing only one or two fans at a lower (altitude and correspondingly higher air pressure).

A variety of other performance parameters, such as internal air or component temperature, ambient air temperature, server workload, and processor activity level, may be factored into fan control. For example, a multivariate correlation between desired fan speed and a plurality of these other parameters may be established. Fan speed and other fan parameters for each subsystem may then be selected according to this predefined, multivariate relationship, of which air-pressure is only one factor.

The steps 100, 102, 104, 106 are arranged in a loop, wherein air-pressure is continuously or periodically sensed according to step 100, and wherein fan parameters such as fan speed are continuously updated, as necessary, in step 106. The sensed air-pressure will generally change infrequently, because once the system is placed in service at a location it tends to remain at about that same altitude. When devices are moved around within a data center, the altitude will usually not change enough to significantly affect the fan speed, though altitude might change significantly if the devices are moved around in a tall building. However, environmental factors may contribute to a change in air pressure that may precipitate the need for adjustment of fan operational parameters despite no appreciable change in altitude. Nonetheless, it is usually not critical in most installations to sense air pressure with a high frequency. Still, an air pressure sensor may, by its design, continuously monitor altitude, and it is acceptable to do so. For example, where the air pressure sensor is a component of an altimeter, the altimeter may constantly monitor air pressure when powered on. A probable scenario wherein air pressure should be updated is where a system is transported from its location of manufacture and testing to its location of final installation, or where a system is transported from one site to another. For example, a server system manufactured and tested in Texas and subsequently shipped to a customer in Colorado would likely undergo a change in altitude, precipitating a need to update the sensed air pressure after being transported from its location of testing in Texas to its new place of service in Colorado. Likewise, if the system was subsequently moved from its original place of service at one address in Colorado to another location in the same state, then altitude would change and the air pressure should probably also be re-sensed. Still, systems may be configured to continuously update air pressure (or an air-pressure-dependent derivative such as altitude), while others may be configured to update air pressure periodically, upon system startup, or simply “on demand” at the request of a user.

The terms “comprising,” “including,” and “having,” as used in the claims and specification herein, shall be considered as indicating an open group that may include other elements not specified. The terms “a,” 37 an,” and the singular forms of words shall be taken to include the plural form of the same words, such that the terms mean that one or more of something is provided. The term “one” or “single” may be used to indicate that one and only one of something is intended. Similarly, other specific integer values, such as “two,” may be used when a specific number of things is intended. The terms “preferably,” “preferred,” “prefer,” “optionally,” “may,” and similar terms are used to indicate that an item, condition or step being referred to is an optional (not required) feature of the invention.

While the invention has been described with respect to a limited number of embodiments, those skilled in the art, having benefit of this disclosure, will appreciate that other embodiments can be devised which do not depart from the scope of the invention as disclosed herein. Accordingly, the scope of the invention should be limited only by the attached claims.

1-9. (canceled)

10. A method of cooling an electronic system having a plurality of heat-generating electronic subsystems, each subsystem having its own on-board fan or blower module having one or more fans, the method comprising:
sensing air-pressure of the electronic system;
generating a signal in relation to the sensed air-pressure;
communicating the signal to each of the electronic subsystems; and
independently controlling one or more fan operational parameters of the fan or blower module for each electronic subsystem in relation to the signal.

11. The method of claim 10, wherein the one or more fan operational parameters include fan speed.

12. The method of claim 10, further comprising controlling the one or more fan operational parameters for each electronic subsystem in relation to one or more of the group consisting of internal air temperature, ambient air temperature, server workload, and processor activity level.
